(19) United States
(12) Patent Application Publication
(10) Pub. No.: US 2026/0001484 A1
(43) Pub. Date: Jan. 1, 2026

(54) TRAILER LIGHT MONITORING MODULE

(71) Applicant: Truck-Lite Co., LLC, Falconer, NY (US)

(72) Inventors: Justin Gregory, Pittsburgh, PA (US); Seth Ammer, Pittsburgh, PA (US); Roger Elmer, Pittsburgh, PA (US)

(21) Appl. No.: 19/250,878

(22) Filed: Jun. 26, 2025

Related U.S. Application Data
(60) Provisional application No. 63/664,389, filed on Jun. 26, 2024.

(51) Int. Cl. B60Q 11/00; G01R 31/00; H05B 47/14

(52) U.S. Cl. CPC B60Q 11/005; G01R 31/007; H05B 47/14; B60Y 2200/148

(57) ABSTRACT

A trailer light monitoring module is configured to electrically couple with lights on a trailer and include an input configured to receive electrical power from a battery; an output configured to electrically couple with lights on a trailer and selectively communicate the electrical power from the battery; a learning button, the activation of which determines a quantity of possible channels through which trailer lights could receive electrical power, and also determines how many of the quantity of possible channels actually receive electrical power; and a plurality of channel diagnostic blocks each including a tunable current sensor having a variable resistor that is tunable based on an output voltage received.

### TECHNICAL DESCRIPTION

The present application relates to semi-trucks and, more particularly, to monitoring systems on trailers used with the semi-trucks.

### BACKGROUND

Modern semi-trucks tow trailers that include a plurality of lights. The lights can have a service life that is uncertain. Monitoring the functionality of the lights included on the trailer can be helpful.

### SUMMARY

According to one aspect of the disclosure, a trailer light monitoring module is configured to electrically couple with lights on a trailer and include an input configured to receive electrical power from a battery; an output configured to electrically couple with lights on a trailer and selectively communicate the electrical power from the battery; a learning button, the activation of which determines a quantity of possible channels through which trailer lights could receive electrical power, and also determines how many of the quantity of possible channels actually receive electrical power; and a plurality of channel diagnostic blocks each including a tunable current sensor having a variable resistor that is tunable based on an output voltage received.

According to another aspect of the disclosure, a trailer light monitoring module is configured to electrically couple with lights on a trailer, and include an input configured to receive electrical power from a battery; an output configured to electrically couple with lights on a trailer and selectively communicate the electrical power from the battery; a plurality of channel diagnostic blocks each including a tunable current sensor having a variable resistor that is tunable based on an output voltage received; and a controller capable of processing electronic instructions, wherein the controller: renders at least one channel associated with trailer lights conductive; measures an output from an analog digital converter (ADC); compares the measured output to a low voltage threshold and a high voltage threshold, that can be chosen or selected based on an output voltage level of the battery; and adjusts the amount of resistance of the variable resistor based on whether the detected voltage exceeds or falls below the thresholds.

### BRIEF DESCRIPTION OF THE DRAWINGS

FIG. 1 is a view depicting an implementation of a semi truck configure to use a trailer light monitoring module;

FIG. 2 is a perspective view depicting an implementation of a trailer light monitoring module;

FIG. 3 is a perspective view depicting an implementation of a trailer light monitoring module;

FIG. 4 is a is a perspective view depicting a portion of an implementation of a trailer light monitoring module;

FIG. 5 is a is a perspective view depicting a portion of an implementation of a trailer light monitoring module;

FIG. 6 is a is a block diagram depicting a portion of an implementation of a trailer light monitoring module;

FIG. 7 is a is a block diagram depicting a portion of an implementation of a trailer light monitoring module;

FIG. 8 is a is a block diagram depicting a portion of an implementation of a trailer light monitoring module;

FIG. 9 is a graph depicting functionality of an implementation of a trailer light monitoring module; and

FIG. 10 is a graph depicting additional functionality of an implementation of a trailer light monitoring module.

### DETAILED DESCRIPTION

Semi-trucks typically include a trailer having a box enclosure for carrying cargo and a tractor that pulls the trailer and its cargo over a road. The tractor includes a number of lights, such as headlights, taillights, and running lights. The trailer also includes a number of lights that may be powered by a trailer battery carried by the trailer, or powered by an electrical umbilical cord electrically connecting the tractor to the trailer. However, given the detachable nature of the tractor/trailer relationship, tractor and/or trailer operators may find it challenging to monitor the functional status of lights carried by the trailer. In typical practice, a tractor operator can physically inspect the functional status of lights on the trailer before a trip. But this initial inspection may not identify subsequent lighting failures on the trailer or a tractor operator may forget to inspect the functionality of the trailer lighting. Also, even if the tractor operator identifies a lighting failure, conveying this information to a trailer operator may be challenging.

It would be helpful to have a trailer light monitoring module in electrical communication with the lights on a trailer to automatically determine whether one or more lights are non-functional. The trailer light monitoring module could be electrically connected to an indicator in the tractor such that the module could send a signal to the tractor triggering an alert indicating a light failure. Or the trailer light monitoring module could be in communication with an on-board telematics device such that the status of the trailer lights could be communicated to a back office. And it would also be helpful to be able to couple the trailer light monitoring module to a trailer without adapting the module to a particular quantity of lights or circuit arrangement found on a particular trailer. That is, the trailer light monitoring module can be installed on any trailer regardless of how the lights are electrically connected. In some implementations, the trailer light monitoring module can have a unique wiring harness for use in a particular fleet. This can permit retrofitting the trailer light monitoring module on existing trailers.

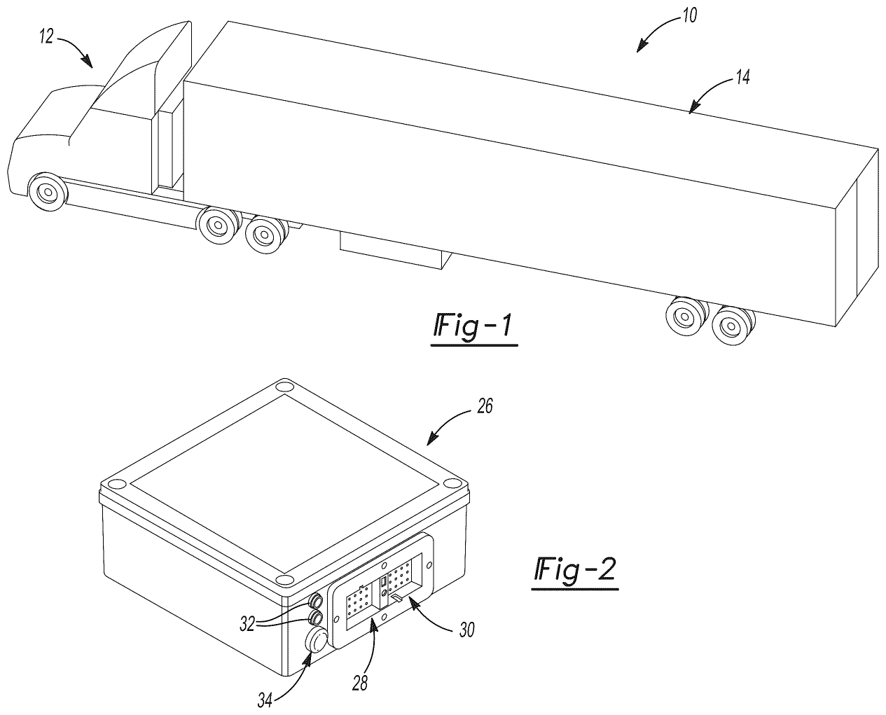

Turning to FIG. 1, an implementation of a semi-truck 10 capable of use with a trailer light monitoring module is shown. While the trailer light monitoring module is shown in the context of a semi-truck, it should be appreciated that the module can be used in other environments as well, such as with box trucks such that the enclosed cargo area is not separated from the propulsion portion of the truck. The semi-truck 10 in this implementation can include a tractor 12 that customarily pulls or propels a trailer 14 mechanically attached to the tractor 12 and capable of carrying cargo. The tractor 12 can be a vehicle powered by an internal combustion engine, such as a diesel engine, that communicates power to wheels and moves the tractor 12. In some implementations the tractor 12 could include an electrical drive train having batteries coupled to an electric motor that propels or moves the tractor. The trailer 14 can include a box enclosure for receiving and carrying cargo and one or more suspension components for buttressing the enclosure and its load against the road surface as the wheels of the trailer 14 engage the road. The trailer 14 can be releasably coupled to the tractor 12 through a fifth-wheel coupling that may be implemented using a kingpin connection. The kingpin can include a vertical shaft extending downwardly from a bottom of the trailer 14. A horseshoe-shaped receptacle at the rear of the tractor 12 can face upwards to pivotably receive the vertical shaft. While the present implementations are described with respect to a detachable trailer, it should be appreciated that other implementations are possible in which the box receiving the cargo is fixed to the tractor, such as in a box truck.

The trailer 14 can include one or more trailer batteries 16 that are used to supply electrical energy to the trailer 14. In some implementations, an electrical cable 18 electrically connects the tractor 12 to the trailer 14 such that electrical power can be supplied from a tractor battery to the trailer 14. To the extent that the following description refers to a trailer battery supplying electrical current, it should be appreciated that a power source from the tractor 12 can supply electrical current to the trailer 14. The electrical cable 18 can also or alternatively include a data bus capable of uni- or bi-directional exchange of data messages or signals between the tractor 12 and the trailer 14. The trailer battery 16 could be implemented as a relatively low voltage battery, ranging from 12-48 volts, that supply energy to electrical components of the trailer 14, such as trailer lights 20. The trailer lights 20 can be incandescent bulbs or light-emitting diodes (LEDs) used to provide illumination. The trailer 14 could optionally include a telematics system 22 that can wirelessly communicate via short-range wireless communication techniques, like Bluetooth or WiFi (802.11), or using cellular communication techniques (e.g., 4GLTE or 5G standards established by 3GPP). However, the electrical components described here could also be used with higher voltage batteries (e.g., >250V) associated with battery electric vehicles.

A controller 24 can be coupled to the trailer batteries 16 such that the controller 24 opens and closes switches that regulate a flow of electrical current from the trailer battery 16 to the trailer lights 20 based on computer-readable instructions. The controller 24 can be any type of device capable of processing electronic instructions including microprocessors, microcontrollers, host processors, controllers, vehicle communication processors, and application specific integrated circuits (ASICs). It can be a dedicated processor used only to direct the functionality of the trailer battery 16 or can be shared with other systems. The controller 24 executes various types of digitally-stored instructions, such as software or firmware programs stored in memory.

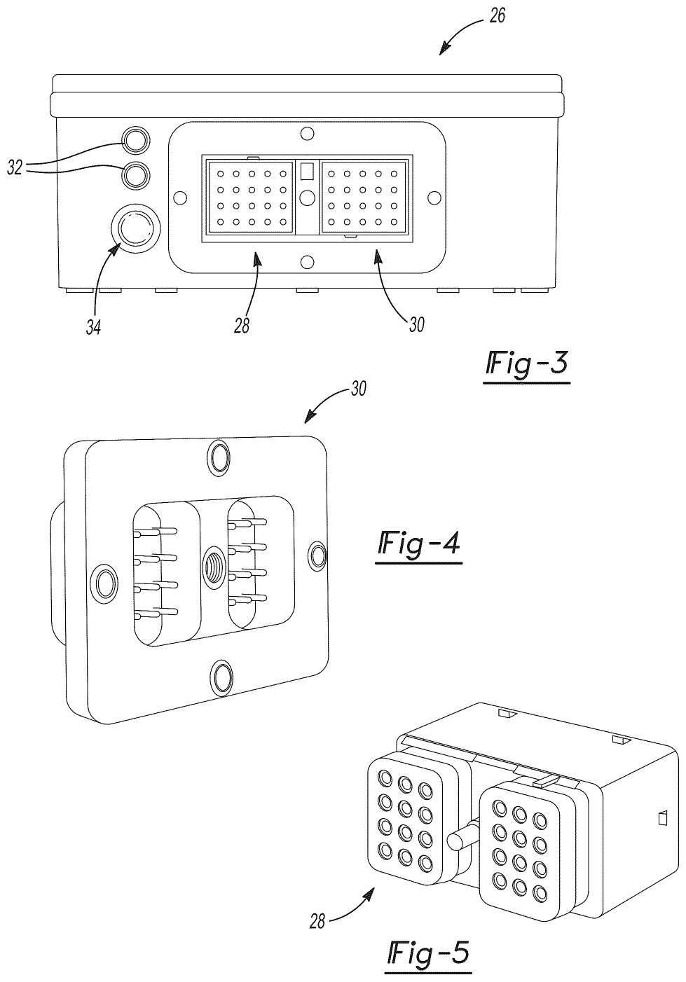

An implementation of a trailer light monitoring module 26 is shown in FIGS. 2-3. The trailer light monitoring module 26 includes an input receptacle 28, an output receptacle 30, a plurality of indicator lights 32, a learning button 34, and a housing 36 for enclosing a plurality of electrical components within the module 26. The trailer light monitoring module 26 is configured to receive input from the controller 24 that activates and deactivates individual trailer lights 20 and generate output that plugs into a wiring harness (not shown) of the trailer 14. That is, the trailer light monitoring module 26 sits inline, or wired in series, relative to a power source providing electrical current to the trailer lights 20, such as the tractor 12 or the trailer battery 16, and the trailer lights 20. The trailer light monitoring module 26 is designed to minimize impedance so as not to be noticeable when installed on a trailer 14. The indicator lights 32 can indicate whether the trailer light monitoring module 26 is operating. The learning button can be depressed by a user and in response the trailer light monitoring module 26 can determine how many channels are currently active such that the trailer battery 16 supplies electrical current to trailer lights through each channel. For example, in one implementation, the trailer light monitoring module 26 can monitor eight channels but the trailer 14 may only conduct current to trailer lights 20 through five of the eight channels. The learning button 34 can direct the trailer light monitoring module 26 to identify the channels through which electrical current flows. The term “learning button” should be interpreted broadly to not only include physically-activated switches but also logical instructions that automatically open and close switches in response to computer-readable instructions. While the example above describes eight channels, it is possible to implement a trailer light monitoring module that has greater or fewer numbers of channels.

An implementation of the output receptacle 30 is shown in FIG. 4 having a twenty-four-pin configuration. The output receptacle 30 can correspond in shape to an output of the trailer battery 16 or the controller 22 such that the output of the trailer battery 16 is disconnected from a trailer wiring harness electrically connected to the trailer lights 20. The output of the trailer light monitoring module 26 can then be electrically coupled to the trailer wiring harness. An implementation of the input receptacle 28 is shown in FIG. 5. The input receptacle 28 of the trailer light monitoring module 26 is configured to match the trailer wiring harness so the output of the trailer battery 14 can be electrically coupled to the input receptacle 28. The implementations of the output receptacle 30 and the input receptacle 28 are one possible selection; it should be appreciated that others are possible depending on the connectors used in a particular wiring harness.

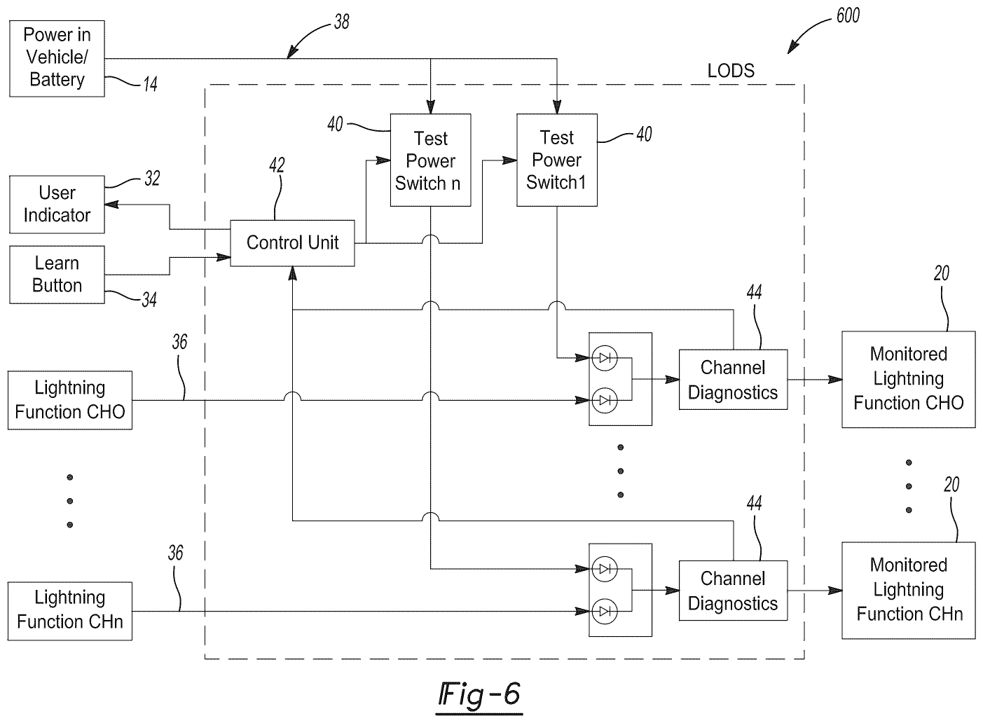

FIG. 6 depicts a block diagram 600 of an implementation of the trailer light monitoring module 26. The trailer light monitoring module 26 includes inputs in the form of a trailer battery 16, the learning button 34, and trailer light inputs from the controller 24. The trailer battery 16 can supply electrical power to the trailer light monitoring module 26 that can be distributed within the trailer light monitoring module 26 via an electrical bus 38. The trailer light monitoring module 26 can include individual power switches 40 for each channel. The power switches 40 can be controlled by a lighting module controller 42 that opens and closes the power switches 40 thereby regulating electrical power provided by the trailer battery 16. The power switches 40 can also include a boost regulator that can provide an elevated voltage in response to a command from the lighting module controller 42. The controller 24 from the trailer 14 can provide logic inputs that open or close power switches 40 thereby activating or deactivating certain trailer lights 20. The quantity of logic inputs can vary based on the number of channels used to operate trailer lights 20 (CH₀ . . . CHₙ). The trailer light monitoring module 26 receives logic inputs from the controller 24 and can communicate the logic inputs to channel diagnostic blocks 44.

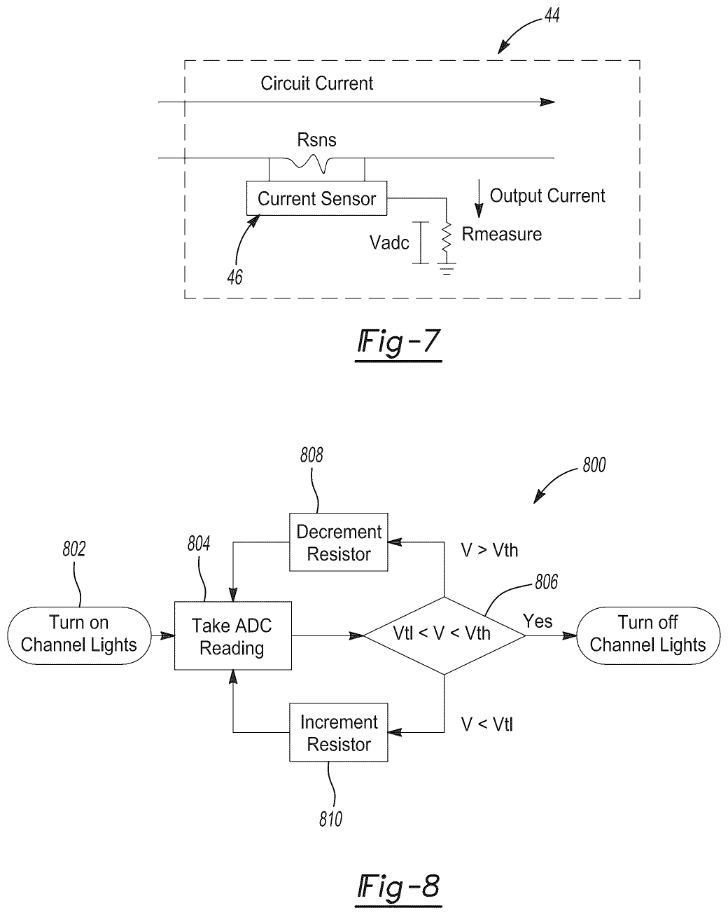

The channel diagnostic blocks 44 can also be in communication with the lighting module controller 42. The channel diagnostic blocks 44 can receive electrical power from the trailer battery 16 through an individual power switch 40 and computer-readable commands from the lighting module controller 42. The channel diagnostic blocks 44 can also be electrically connected to the trailer lights 20 of a particular channel. An implementation of a channel diagnostic block 44 is shown in more detail with regard to FIG. 7.

The channel diagnostic block can include a tunable current sensor 46 that may receive electrical power from the trailer battery 20, which is ultimately supplied to the trailer lights 20. The current sensor 46 can use a shunt resistor (Rₛₙₛ) that determines an initial current value given a voltage across the shunt resistor and Ohm's law. The channel diagnostic block 44 can include a variable resistor (Rₘₑₐₛᵤᵣₑ) that can be adjusted based on an output voltage received at the channel diagnostic block 44. Given the trailer light monitoring module 26 may be used with a variety of different trailers 14, the output voltage received at the channel diagnostic block 44 may vary significantly. In one implementation, the variable resistor can be set based on a voltage value such that voltage measurements based on the received output voltage at the variable resistor are 60-80% of an ADC reading to prevent saturation. The learning button 34 can be depressed to initiate a method 800 that establishes a resistance value used by the variable resistor. An implementation of the method is shown at 800.

The method 800 begins at step 802 by activating, or rendering conductive, a channel associated with trailer lights 20. The lighting module controller 42 can take an analog digital converter (ADC) measurement at step 804 detecting a voltage (V) across the variable resistor. The method 800 proceeds to step 806 where the detected voltage is compared to a low voltage threshold (Vₜₗ) and a high voltage threshold (Vₜₕ), that can be chosen or selected based on an output voltage level of the trailer battery 16. In one implementation, the low voltage threshold (Vₜₗ) can be set at 60% of saturation voltage and the high voltage threshold (Vₜₕ) can be set at 80% of saturation voltage. If the voltage (V) measured across the variable resistor is higher than the high voltage threshold (Vₜₕ), then the method 800 proceeds to step 808 where the amount of resistance of the variable resistor is decreased and the method 800 returns to step 804. If the voltage (V) measured across the variable resistor is lower than the low voltage threshold (Vₜₗ), then the method proceeds to step 810 where the amount of resistance of the variable resistor is increased and the method 800 returns to step 804. If the voltage (V) measured across the variable resistor is lower than the high voltage threshold (Vₜₕ) and higher than the low voltage threshold (Vₜₗ), then then the method 800 proceeds to step 812 and the channel associated with the trailer lights 20 is deactivated. This process is repeated for every channel associated with at least one trailer light 20 and every channel diagnostic block 444. The channel diagnostic block 44 can then measure an initial current value for each channel and store the initial current value in non-volatile memory. The light module controller 42 can include an onboard memory module for this purpose.

The initial current value can be used to determine whether one or more trailer lights 20 included or electrically connected to a channel have failed. The failure of one or more trailer lights 20 will reduce the amount of current flowing through a channel in a predictable way. Similarly, an increase in voltage input to the trailer light monitoring module 26 can also have a predictable affect on the amount of current flowing through the channel. Given the initial current value and a measured amount of voltage at the trailer light monitoring module 26, the module 26 can apply a boosted voltage to the channel, determine a subsequent current value, and create a current-voltage function based on these measurements. The current-voltage function can then be used to monitor the channel to determine if the current drops more than a defined threshold, and, if so, an alarm can be triggered indicating that one or more trailer lights have failed.

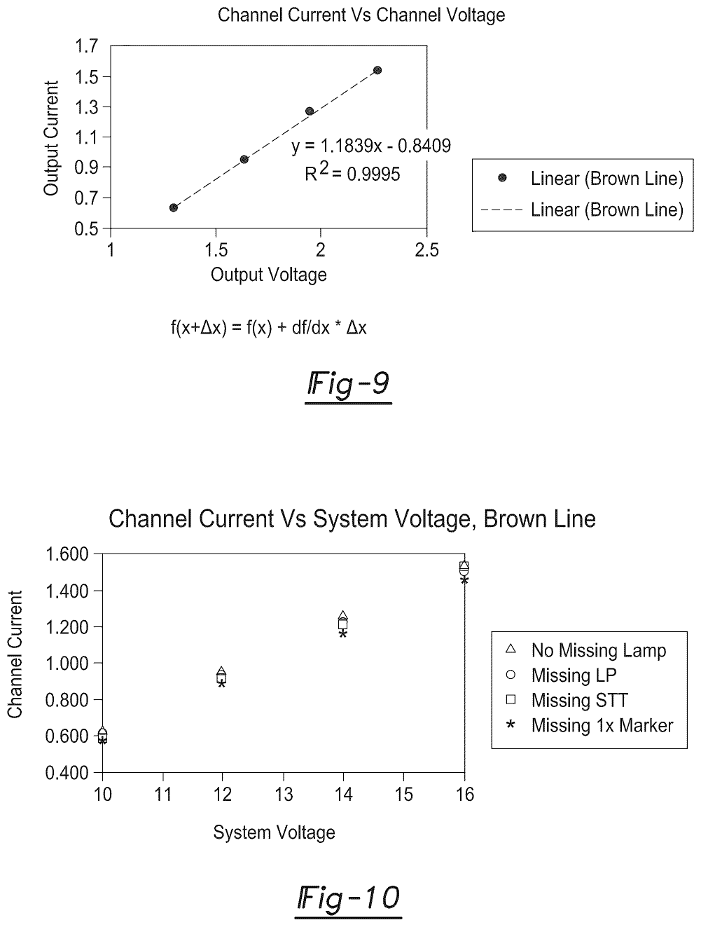

An implementation of this is reflected in FIGS. 9 and 10. FIG. 9 depicts an initial voltage value and an initial current value measured at the variable resistor. A boosted voltage can be supplied to the channel diagnostic block 44 and a subsequent current value measured at the variable resistor. The boosted voltage can be created at the power switches 40 using a switching regulator having a capacitor and an inductor to boost the voltage received at the trailer light monitoring module 26. The two values, the initial current value and the subsequent current value along with the initial voltage and the boosted voltage can be used to create the current-voltage function. The current-voltage function can be created using regression analysis and the two coordinate points.

FIG. 10 depicts application of the current-voltage function to a particular channel. As the electrical current flowing through a particular channel falls, the amount of the current fall can be determined and based on the amount, it can be determined that a trailer light 20 has failed. The channel diagnostic block can output a flag that can activate a warning light in the tractor 12, generate a message that is sent to the telematics system 20, which can wirelessly transmit the message to a back office.

It is to be understood that the foregoing is a description of one or more embodiments of the invention. The invention is not limited to the particular embodiment(s) disclosed herein, but rather is defined solely by the claims below. Furthermore, the statements contained in the foregoing description relate to particular embodiments and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art. All such other embodiments, changes, and modifications are intended to come within the scope of the appended claims.

As used in this specification and claims, the terms “e.g.,” “for example,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation.

1. A trailer light monitoring module configured to electrically couple with lights on a trailer, comprising:
an input configured to receive electrical power from a battery;
an output configured to electrically couple with lights on a trailer and selectively communicate the electrical power from the battery;
a learning button, the activation of which determines a quantity of possible channels through which trailer lights could receive electrical power, and also determines how many of the quantity of possible channels actually receive electrical power; and
a plurality of channel diagnostic blocks each including a tunable current sensor having a variable resistor that is tunable based on an output voltage received.

2. The trailer light monitoring module recited in claim 1, further comprising an individual switch for each of the quantity of possible channels.

3. The trailer light monitoring module recited in claim 1, further comprising a boost regulator that supplies an elevated voltage to the quantity of possible channels.

4. The trailer light monitoring module recited in claim 1, wherein each of the plurality of channel diagnostic blocks each includes a shunt resistor that determines an initial current value given a voltage across the shunt resistor.

5. The trailer light monitoring module recited in claim 1, wherein the variable resistor is set for an output voltage that is 60-80% of saturation.

6. A trailer light monitoring module configured to electrically couple with lights on a trailer, comprising:
an input configured to receive electrical power from a battery;
an output configured to electrically couple with lights on a trailer and selectively communicate the electrical power from the battery;
a plurality of channel diagnostic blocks each including a tunable current sensor having a variable resistor that is tunable based on an output voltage received; and
a controller capable of processing electronic instructions, wherein the controller:
renders at least one channel associated with trailer lights conductive;
measures an output from an analog digital converter (ADC);
compares the measured output to a low voltage threshold and a high voltage threshold, that can be chosen or selected based on an output voltage level of the battery; and
adjusts the amount of resistance of the variable resistor based on whether the detected voltage exceeds or falls below the thresholds.

7. The trailer light monitoring module recited in claim 6, further comprising a learning button, the activation of which determines a quantity of possible channels through which trailer lights could receive electrical power, and also determines how many of the quantity of possible channels actually receive electrical power.

8. The trailer light monitoring module recited in claim 6, further comprising an individual switch for each of the quantity of possible channels.

9. The trailer light monitoring module recited in claim 6, further comprising a boost regulator that supplies an elevated voltage to the quantity of possible channels.

10. The trailer light monitoring module recited in claim 6, further comprising a shunt resistor that determines an initial current value given a voltage across the shunt resistor.

11. The trailer light monitoring module recited in claim 6, wherein the variable resistor is set for an output voltage that is 60-80% of saturation.
